(19) United States
(12) Patent Application Publication
(10) Pub. No.: US 2025/0347831 A1
(43) Pub. Date: Nov. 13, 2025

(54) LIGHT GUIDE PLATE, IMAGE DISPLAY DEVICE, AND METHOD OF MANUFACTURING LIGHT GUIDE PLATE

(71) Applicant: SONY GROUP CORPORATION, Tokyo (JP)

(72) Inventors: Kazue SHIMIZU, Kanagawa (JP); Kentaro KATO, Kanagawa (JP); Christophe PEROZ, Tokyo (JP); Chieh CHANG, New Taipei City (TW)

(73) Assignee: SONY GROUP CORPORATION, Tokyo (JP)

(21) Appl. No.: 18/860,089

(22) PCT Filed: Mar. 29, 2023
(86) PCT No.: PCT/JP2023/012856

§ 371 Date: Oct. 25, 2024

(30) Foreign Application Priority Data
May 2, 2022 (JP) 2022-076079

(51) Int. Cl. G02B 5/18; B29D 11/00; G02B 6/34; G02B 27/01

(52) U.S. Cl. CPC G02B 5/1809; B29D 11/00663; G02B 5/1852; G02B 6/34; G02B 27/0172

(57) ABSTRACT

There are provided a light guide plate, an image display device, and a method of manufacturing a light guide plate that suppress deterioration of the image quality even when the amount of a resin material cannot be strictly controlled. Provided is a light guide plate including: a diffraction grating that diffracts light; a layer thickness adjustment unit formed adjacent to the diffraction grating; and a substrate that totally internally reflects and guides light, in which the layer thickness adjustment unit includes an uneven region having a predetermined pitch or a blank region having a predetermined layer thickness, or both of the uneven region and the blank region.

### TECHNICAL FIELD

The present technology relates to a light guide plate, an image display device, and a method of manufacturing a light guide plate.

### BACKGROUND ART

Conventionally, in order to realize extended reality (XR) including augmented reality (AR), virtual reality (VR), mixed reality (MR), and the like, a light guide plate that emits image light to the pupil of an observer has been developed.

A diffraction grating that diffracts the image light is used in the light guide plate. A nanoimprint method can be used as an example of a method of forming the diffraction grating. The nanoimprint method is a method of forming a resin pattern having an uneven shape by pressing a mold on which an uneven pattern is formed against a resin material and then curing the resin material. For example, in Patent Documents 1 and 2, there are disclosed that such nanoimprint method is used.

### CITATION LIST

### Patent Document

Patent Document 1: U.S. Patent Application Publication No. 2005/0270312
Patent Document 2: U.S. Patent Application Publication No. 2020/0333527

### SUMMARY OF THE INVENTION

### Problems to be Solved by the Invention

In a nanoimprint method, strict control of the amount of a resin material is required. In a case where the amount of the resin material is inappropriate, the formation of a diffraction grating becomes insufficient, and thus, for example, disturbance of a wavefront, dispersion of the diffraction efficiency, and the like may occur. Therefore, the image quality may deteriorate. However, it is very difficult to strictly control the amount of the resin material by using an existing inkjet system.

Therefore, a main object of the present technology is to provide a light guide plate, an image display device, and a method of manufacturing a light guide plate that suppress deterioration of the image quality even when the amount of the resin material cannot be strictly controlled.

### Solutions to Problems

The present technology provides a light guide plate including: a diffraction grating that diffracts light; a layer thickness adjustment unit formed adjacent to the diffraction grating; and a substrate that totally internally reflects and guides light, in which the layer thickness adjustment unit includes an uneven region having a predetermined pitch or a blank region having a predetermined layer thickness, or both of the uneven region and the blank region.

A pitch Λ of the uneven region may satisfy the following Formula (1)

$$[ Mathematical formula 1 ]$$

$$Λ < \frac{{n}_{2} - {n}_{1} sin θ}{λ} , \qquad ( 1 )$$

where a refractive index of air existing around the light guide plate is n1, a refractive index of the layer thickness adjustment unit is n2, a side-view incident angle of light incident on the layer thickness adjustment unit is θ, and a wavelength of light existing around the light guide plate is λ.

A height of the uneven region may be different from a height of the diffraction grating.

The height of the uneven region may change according to a distance from the diffraction grating.

The height of the uneven region may decrease as the distance from the diffraction grating increases.

A duty cycle of the uneven region may be different from a duty cycle of the diffraction grating.

The duty cycle of the uneven region may change according to the distance from the diffraction grating.

The duty cycle of the uneven region may decrease as the distance from the diffraction grating increases.

A layer thickness of the blank region may change according to the distance from the diffraction grating.

The layer thickness of the blank region may increase as the distance from the diffraction grating increases.

A width of the layer thickness adjustment unit may be 0.1 mm or more.

The diffraction grating may be an incident diffraction grating, an emission diffraction grating, an extended diffraction grating, or a return diffraction grating.

The uneven region may have a grating vector substantially the same as the diffraction grating, and diffraction efficiency of the uneven region may be 3% or less.

A diameter of the diffraction grating may be less than 2 mm.

The layer thickness adjustment unit may be formed around the diffraction grating.

The layer thickness adjustment unit may be formed between two of the diffraction gratings.

The layer thickness adjustment unit may be formed between and around the two diffraction gratings.

In addition, the present technology provides an image display device including: the light guide plate; and an image forming unit that emits image light to the light guide plate.

Furthermore, the present technology provides a method of manufacturing a light guide plate by a nanoimprint method, the method, at least, including: forming a resin material on a surface of a substrate; pressing a mold against the resin material; curing the resin material by irradiating the resin material with ultraviolet rays in a state where the mold is pressed against the resin material to transfer a master pattern of the mold to the resin material; and separating the mold from the resin material to form a resin pattern on the resin material, in which the master pattern includes a first uneven pattern that forms a diffraction grating that diffracts light, and a second uneven pattern that forms an uneven region having a predetermined pitch or a second blank region that forms a first blank region having a predetermined layer thickness, or both of the second uneven pattern and the second blank region.

According to the present technology, it is possible to provide a light guide plate, an image display device, and a method of manufacturing a light guide plate that suppress deterioration of the image quality even when the amount of the resin material cannot be strictly controlled. Note that the effects described herein are not necessarily restrictive, and any of the effects described in the present disclosure may be exhibited.

### BRIEF DESCRIPTION OF DRAWINGS

FIG. 1 is a simplified front view illustrating a configuration example of a light guide plate 1 according to an embodiment of the present technology.

FIG. 2 is wave number space coordinates indicating a design example of a grating vector according to an embodiment of the present technology.

FIG. 3 is a schematic view illustrating an example of a method of manufacturing the light guide plate 1 according to an embodiment of the present technology.

FIG. 4 is a simplified top view illustrating the configuration example of the light guide plate 1 according to an embodiment of the present technology.

FIG. 5 is a cross-sectional view taken along line A-A illustrated in FIG. 4.

FIG. 6 is a graph obtained by plotting the thickness of a resin material in a cross section taken along line A-A illustrated in FIG. 4.

FIG. 7 is wave number space coordinates indicating the design example of the grating vector according to an embodiment of the present technology.

FIG. 8 is a schematic diagram illustrating a side-view incident angle θ.

FIG. 9 is a cross-sectional view taken along line A-A illustrated in FIG. 4.

FIG. 10 is a cross-sectional view taken along line A-A illustrated in FIG. 4.

FIG. 11 is a simplified top view illustrating a configuration example of a light guide plate 1 according to an embodiment of the present technology.

FIG. 12 is a graph obtained by plotting the thickness of a resin material in a cross section taken along line A-A illustrated in FIG. 11.

FIG. 13 is a simplified side view illustrating a configuration example of a light guide plate 1 according to an embodiment of the present technology.

FIG. 14 is a simplified side view illustrating the configuration example of the light guide plate 1 according to an embodiment of the present technology.

FIG. 15 is a graph obtained by plotting the thickness of a resin material formed on the light guide plate 1 according to an embodiment of the present technology.

FIG. 16 is a simplified side view illustrating a configuration example of a light guide plate 1 according to an embodiment of the present technology.

FIG. 17 is a cross-sectional view taken along line A-A illustrated in FIG. 26.

FIG. 18 is a schematic view illustrating an example of a method of manufacturing a light guide plate 1 according to an embodiment of the present technology.

FIG. 19 is a schematic view illustrating the example of the method of manufacturing the light guide plate 1 according to an embodiment of the present technology.

FIG. 20 is a schematic view illustrating the example of the method of manufacturing the light guide plate 1 according to an embodiment of the present technology.

FIG. 21 is a block diagram illustrating a configuration example of an image display device 10 according to an embodiment of the present technology.

FIG. 22 is a flowchart indicating an example of a procedure of a method of manufacturing a light guide plate according to an embodiment of the present technology.

FIG. 23 is a simplified top view illustrating a configuration example of a diffraction grating 20 formed by using a nanoimprint method.

FIG. 24 is a cross-sectional view taken along line A-A illustrated in FIG. 23.

FIG. 25 is a table indicating a relationship between an amount of the resin material used in the nanoimprint method and a resin pattern to be formed.

FIG. 26 is a simplified top view illustrating the configuration example of a first diffraction grating 20a and a second diffraction grating 20b formed by using the nanoimprint method.

FIG. 27 is a cross-sectional view taken along line A-A illustrated in FIG. 26.

FIG. 28 is a table indicating a relationship between an amount of the resin material used in the nanoimprint method and a resin pattern to be formed.

### MODE FOR CARRYING OUT THE INVENTION

Hereinafter, preferred embodiments for carrying out the present technology will be described with reference to the drawings. Note that the embodiments described later each illustrates an example of a representative embodiment of the present technology, and the scope of the present technology is not limited by this. Furthermore, in the present technology, any of the following examples and modifications thereof can be combined.

In the following description of the embodiments, the configuration may be described using terms with “substantially” such as substantially parallel and substantially orthogonal. For example, “substantially parallel” means not only being completely parallel, but also includes being substantially parallel, that is, a state shifted by, for example, about several percent from the completely parallel state. This similarly applies to other terms with “substantially”. Furthermore, each drawing is a schematic view and is not necessarily strictly illustrated.

Unless otherwise specified, in the drawings, “upper” means an upward direction or an upper side in the drawing, “lower” means a downward direction or a lower side in the drawing, “left” means a leftward direction or a left side in the drawing, and “right” means a rightward direction or a right side in the drawing. In addition, in the drawings, the same or equivalent elements or members are denoted by the same reference signs, and redundant description will be omitted.

The description is given in the following order.
1. First Embodiment (Example 1 of Light Guide Plate)
(1) Outline
(2) Layer thickness adjustment unit
(3) Comparison with conventional technology
2. Second Embodiment (Example 2 of Light Guide Plate)
3. Third Embodiment (Example 3 of Light Guide Plate)
4. Fourth Embodiment (Example 4 of Light Guide Plate)
5. Fifth Embodiment (Example 5 of Light Guide Plate)
6. Sixth Embodiment (Example 6 of Light Guide Plate)
7. Seventh Embodiment (Example 7 of Light Guide Plate)
8. Eighth Embodiment (Example 8 of Light Guide Plate)
9. Ninth Embodiment (Example of Image Display Device)
10. Tenth Embodiment (Example of Method of Manufacturing Light Guide Plate)

### 1. First Embodiment (Example 1 of Light Guide Plate)

### (1) Outline

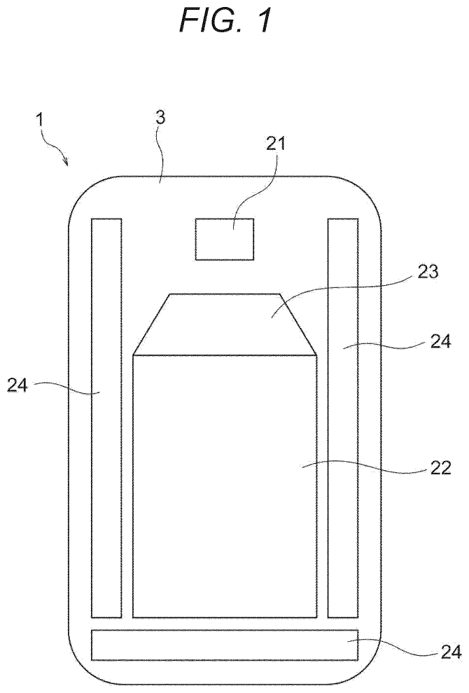

A light guide plate according to an embodiment of the present technology will be described with reference to FIG. 1. FIG. 1 is a simplified front view illustrating a configuration example of a light guide plate 1 according to an embodiment of the present technology. As illustrated in FIG. 1, the light guide plate 1 according to the embodiment of the present technology includes an incident diffraction grating 21, an emission diffraction grating 22, an extended diffraction grating 23, return diffraction gratings 24, and a substrate 3. Note that the light guide plate 1 is not required to include diffraction gratings such as the extended diffraction grating 23 or the return diffraction gratings 24, for example.

The incident diffraction grating 21 diffracts light incident from, for example, an image forming unit (not illustrated), which forms image light, into the light guide plate 1. The substrate 3 totally internally reflects and guides the light diffracted into the light guide plate 1 by the incident diffraction grating 21. The extended diffraction grating 23 diffracts the light guided by the substrate 3 and spreads the light outward (“outward” refers to a direction orthogonal, in a front view, to the axis of the light incident into the light guide plate from the incident diffraction grating. This similarly applies hereinafter.). The emission diffraction grating 22 diffracts the light guided by the substrate 3 to spread the light outward, return the light inward, or emit the light to the pupil of an observer. Each of the return diffraction gratings 24 diffracts and reflects the light, which is traveling outward of the light guide plate 1, inward, thereby improving the utilization efficiency of the light. Note that the diffraction gratings is not necessarily separated physically from each other.

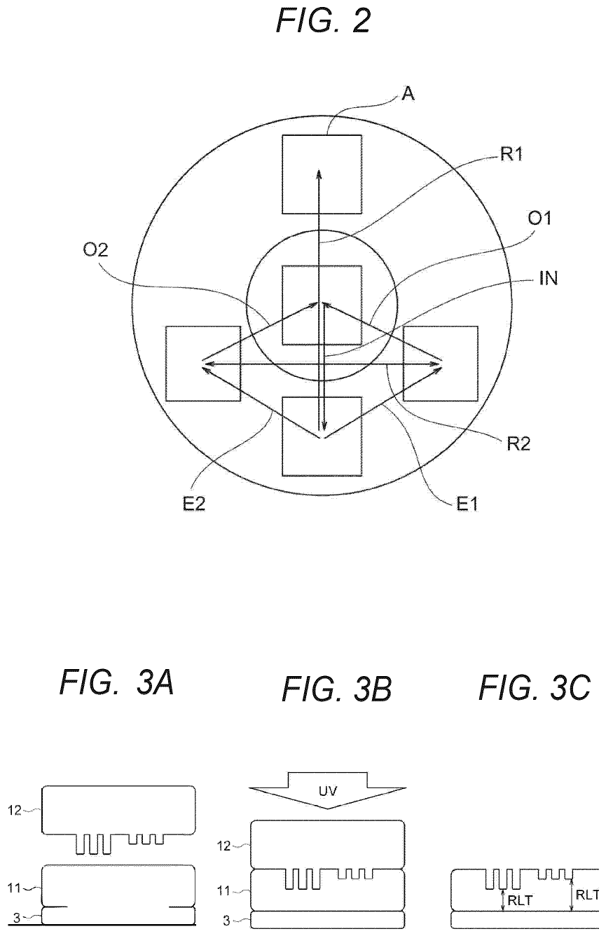

A design example of a grating vector of each diffraction grating will be described with reference to FIG. 2. FIG. 2 is wave number space coordinates indicating a design example of a grating vector according to an embodiment of the present technology. In FIG. 2, grating vectors IN, E1, E2, O1, O2, R1, and R2 and an angle-of-view area A are indicated.

The grating vector IN indicates a grating vector of the incident diffraction grating 21. The grating vectors E1 and E2 indicate grating vectors that spread and diffract light outward in a front view of the light guide plate 1 among grating vectors of the emission diffraction grating 22. Alternatively, the grating vectors E1 and E2 indicate grating vectors of the extended diffraction grating 23. The grating vectors O1 and O2 indicate basic grating vectors for emission to the pupil of the observer among the grating vectors of the emission diffraction grating 22. The grating vectors R1 and R2 indicate grating vectors of the return diffraction grating 24. Each of the grating vectors E1 and E2 and the grating vectors O1 and O2 exists on the front and back surfaces of the substrate 3. Note that each of the grating vectors E1 and E2 and the grating vectors O1 and O2 may exist only on one surface of the substrate 3.

In this design example, the grating vectors IN, E1, and O1 form a triangle. The sum of the grating vector IN, the grating vector E1, and the grating vector O1 is 0. Similarly, the grating vectors IN, E2, and O2 form a triangle. The sum of the grating vector IN, the grating vector E2, and the grating vector O2 is 0. Therefore, deterioration of the image quality can be suppressed. As the difference increases, the image quality deteriorates.

For example, a surface relief grating (SRG) or the like can be used as the diffraction grating such as the incident diffraction grating 21. A volume phase holographic grating (VPHG) may be used as a part of the diffraction grating included in the light guide plate 1. In a case where the volume phase holographic grating is used, a plurality of diffraction gratings may be formed on the same plane, or a plurality of diffraction gratings may be stacked. Hereinafter, the surface relief grating will be described as an example of the diffraction grating.

Conventionally, a nanoimprint method has been used as an example of a method of forming a diffraction grating. The nanoimprint method is a method of forming a resin pattern having an uneven shape by pressing a mold on which an uneven pattern is formed against a resin material and then curing the resin material. Since the nanoimprint method has a high throughput and few handling steps, and each step is simple, the manufacturing cost can be considerably reduced as compared with photolithography. The nanoimprint method will be described with reference to FIG. 3. FIG. 3 is a schematic view illustrating an example of a method of manufacturing the light guide plate 1 according to an embodiment of the present technology.

First, as illustrated in FIG. 3A, a resin material (resist) 11 is applied to the substrate 3. Next, as illustrated in FIG. 3B, a mold 12 on which the uneven pattern is formed is pressed against the resin material 11, and the resin material 11 is irradiated with ultraviolet rays UV to be cured. Then, as illustrated in FIG. 3C, the resin pattern 11 having an uneven shape is formed. The resin pattern 11 having the uneven shape functions as a diffraction grating. A residual layer is formed between the diffraction grating and the substrate 3. A residual layer thickness RLT, which is the thickness of the residual layer, varies depending on various parameters.

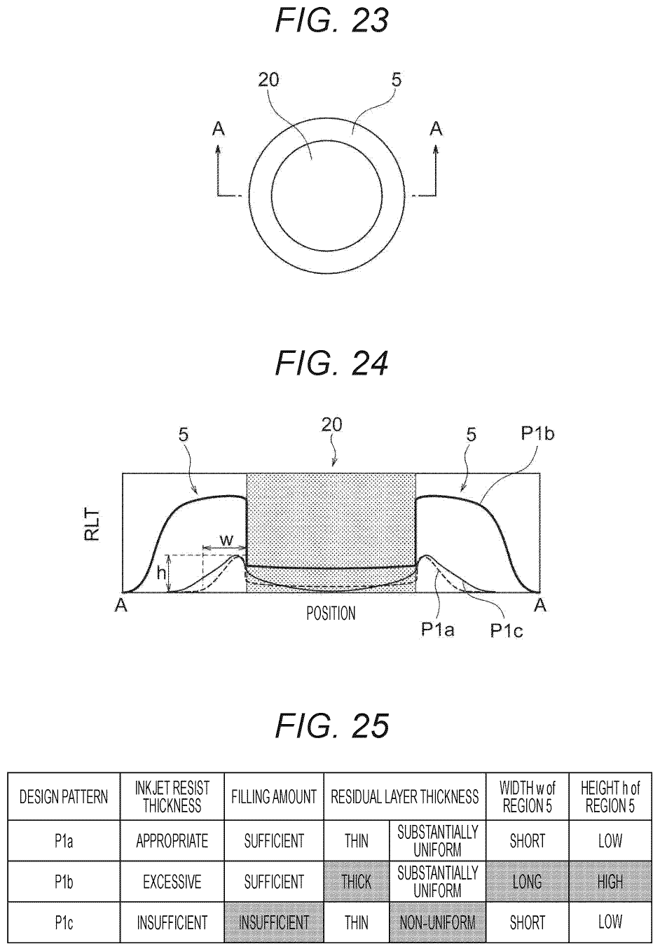

Issues of the nanoimprint method will be described with reference to FIGS. 23 to 25. FIG. 23 is a simplified top view illustrating a configuration example of a diffraction grating 20 formed by using the nanoimprint method. As illustrated in FIG. 23, when the mold is pressed against the resin material, the resin material is pushed out around the diffraction grating 20. As a result, a region 5 in which the resin material swells is formed around the diffraction grating 20.

FIG. 24 is a cross-sectional view taken along line A-A illustrated in FIG. 23. FIG. 25 is a table indicating a relationship between an amount of the resin material used in the nanoimprint method and a resin pattern to be formed. FIGS. 24 and 25 indicate a design pattern P1a in which the amount of the resin material (inkjet resist thickness) is appropriately controlled for each position, a design pattern P1b in which the amount of the resin material is excessive, and a design pattern P1c in which the amount of the resin material is insufficient.

As indicated in FIGS. 24 and 25, the design pattern P1a is a design pattern in which the ideal residual layer thickness is formed by strict control of the resin material. The light can be diffracted as designed. In addition, the residual layer thickness, which is the thickness of the residual layer of the diffraction grating 20, is thin and substantially uniform. As a result, the disturbance of the wavefront can be suppressed, the diffraction efficiency is improved, and the dispersion of the diffraction efficiency can be suppressed. In a case where the refractive index of the resin material is lower than the refractive index of the substrate 3, the residual layer is preferably thin. Furthermore, a width w of the region 5 in which the resin material is pushed out around the diffraction grating 20 is short, and a height h of the region 5 is low. This makes it possible to suppress a decrease in a modulation transfer function (MTF).

On the other hand, in a general inkjet method, in a case where a mold is sufficiently filled with a resin material in order to manufacture the diffraction grating to have a height as designed, the diffraction grating is formed to have the height as designed and the residual layer thickness is substantially uniform, but the residual layer thickness is large. As a result, in a case where the refractive index of the resin is lower than the refractive index of the light guide plate (substrate), the diffraction efficiency is reduced at some angles of view. In addition, regardless of the refractive index of the resin material, the absorption increases when the resin material has relatively large absorption. This causes an issue of efficiency reduction. Furthermore, since the amount of the resin material is excessive, the width w of the region 5 in which the resin material is pushed out around the diffraction grating 20 is long, and the height h of the region 5 is high. Therefore, there arises an issue that the MTF is decreased and the image quality is deteriorated.

Meanwhile, in the design pattern P1c in which the amount of the resin material is reduced in order to reduce the amount of the resin in the region 5 pushed out around the diffraction grating 20, the diffraction grating 20 is not sufficiently filled with the resin, and it is difficult to achieve the diffraction efficiency as designed. The width w of the region 5 in which the resin material is pushed out around the diffraction grating 20 is short, and the height h of the region 5 is low. However, since the amount of the resin material is insufficient, the amount of the resin material for filling the diffraction grating is insufficient. Therefore, diffraction efficiency cannot be achieved as designed. As a result, efficiency and luminance uniformity are affected, causing deterioration of the image quality. Furthermore, since the amount of the resin material is insufficient, the residual layer thickness is non-uniform. This causes disturbance of the wavefront and dispersion of the diffraction efficiency. As a result, there arises an issue that the resolution is deteriorated.

In order to form an ideal resin pattern, it is preferable to strictly control the amount of the resin material. However, in a case where an existing inkjet system is used, it is very difficult to strictly control the amount of the resin material. Therefore, it is difficult to form the ideal resin pattern.

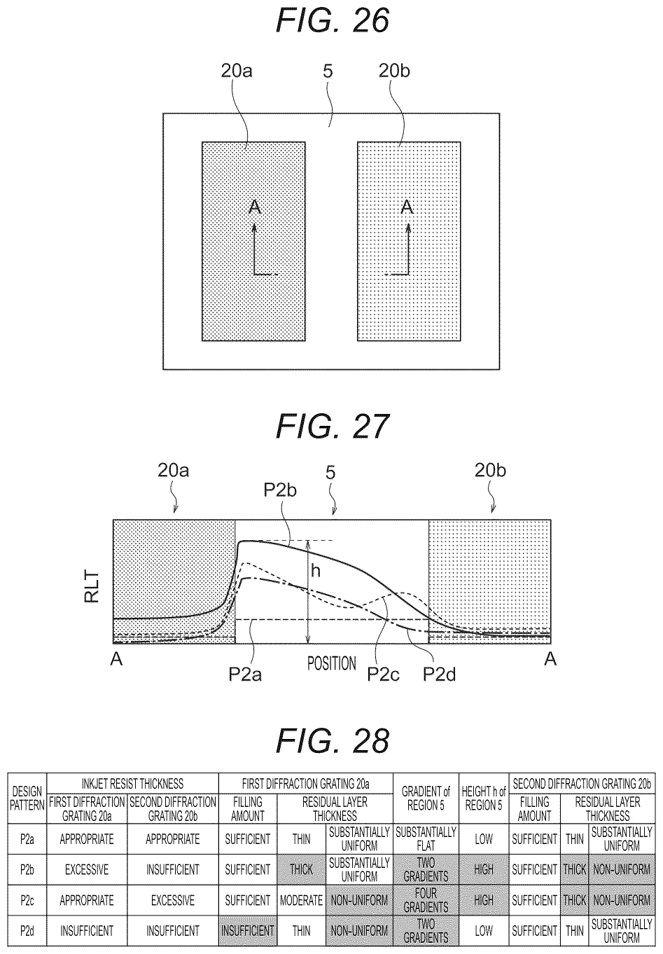

The problems of the nanoimprint method will be further described with reference to FIGS. 26 to 28. FIG. 26 is a simplified top view illustrating a configuration example of a first diffraction grating 20a and a second diffraction grating 20b formed by using the nanoimprint method. As illustrated in FIG. 26, the first diffraction grating 20a and the second diffraction grating 20b are formed at positions close to each other. The region 5, in which the resin material is pushed out when the mold is pressed against the resin material, is formed around each of the first diffraction grating 20a and the second diffraction grating 20b. Note that, although not illustrated, the height of the first diffraction grating 20a is higher than the height of the second diffraction grating 20b. Therefore, the amount of the resin material for filling the first diffraction grating 20a tends to be larger than the amount of the resin material for filling the second diffraction grating 20b. Note that the heights of the first diffraction grating 20a and the second diffraction grating 20b may be substantially the same.

FIG. 27 is a cross-sectional view taken along line A-A illustrated in FIG. 26. FIG. 28 is a table indicating a relationship between the amount of the resin material used in the nanoimprint method and a resin pattern to be formed. In FIGS. 27 and 28, design patterns P2a to P2d are indicated. The design pattern P2a is an ideal design pattern formed by strict control of the resin material for each of the first diffraction grating 20a and the second diffraction grating 20b. In the design pattern P2b, the amount of the resin material for the first diffraction grating 20a is excessive, and the amount of the resin material for the second diffraction grating 20b is insufficient. In the design pattern P2c, the amount of the resin material for the first diffraction grating 20a is appropriate, and the amount of the resin material for the second diffraction grating 20b is excessive. In the design pattern P2d, the amount of the resin material is insufficient for each of the first diffraction grating 20a and the second diffraction grating 20b.

As indicated in FIGS. 27 and 28, in the design pattern P2a in which the amount of the resin material is appropriate, the amount of the resin material for filling each of the first diffraction grating 20a and the second diffraction grating 20b is sufficient. In addition, the residual layer thickness of each of the first diffraction grating 20a and the second diffraction grating 20b is thin and substantially uniform.

The first diffraction grating 20a and the second diffraction grating 20b are formed at positions close to each other. Therefore, for example, the region 5 formed on an optical path from the first diffraction grating 20a to the second diffraction grating 20b or on an optical path in the opposite direction affects the wavefront of light. Therefore, it is preferable that the region 5 formed between the first diffraction grating 20a and the second diffraction grating 20b have a low height h and be substantially flat. This makes it possible to suppress a decrease in the MTF.

In a case where a plurality of diffraction gratings is adjacent to each other, the residual layer thicknesses of the diffraction gratings are affected by each other. For example, in a case where the filling amount of the resin material for the region of the first diffraction grating 20a is increased and the filling amount of the resin material for the second diffraction grating 20b having a low height is decreased in consideration of the filling rate to the diffraction grating having a high height, the resin material is pushed out from the side where a large amount of resin material is applied to the side where a small amount of resin material is applied, and as a result, the residual layer thicknesses of both the first diffraction grating 20a and the second diffraction grating 20b are increased, as indicated in the design pattern P2b. The residual layer thickness is substantially uniform on the first diffraction grating 20a side where the amount of the resin material is increased, but the residual layer thickness becomes non-uniform on the second diffraction grating 20b side where the resin material pushed out is flowed in. In addition, the height of the region 5 existing between the first diffraction grating 20a and the second diffraction grating 20b also increases, leading to deterioration of the image quality such as resolution.

In the design pattern P2c, since the filling amount for the first diffraction grating 20a is excessive, the amount of the resin material is reduced to an appropriate amount. In this case, the residual layer thickness is a moderate thickness but non-uniform, and still the resin material flows into the second diffraction grating 20b side, causing the residual layer thickness to be thick and non-uniform. In the region 5 existing between the first diffraction grating 20a and the second diffraction grating 20b, two peaks are formed and four gradients are formed. Therefore, there is a possibility that the MTF decreases.

The design pattern P2d is an example of a case where the filling amount for the first diffraction grating 20a is reduced in order to make the residual layer thickness thin. The residual layer thickness of each of the first diffraction grating 20a and the second diffraction grating 20b is thin. In the second diffraction grating 20b, the residual layer thickness becomes substantially uniform due to a decrease in the amount of the resin material flowing in, and the filling the diffraction grating with the resin material is sufficient. On the other hand, in the first diffraction grating 20a, the residual layer thickness is non-uniform, and the filling the diffraction grating with the resin material is insufficient. As described above, in a case where the plurality of diffraction gratings is adjacent to each other and also the heights of the respective diffraction gratings are different from each other, it is very difficult to sufficiently fill the diffraction grating with the resin material with only the conventional injection technique.

### (2) Layer Thickness Adjustment Unit

In order to solve such an issue, the present technology provides a light guide plate including: a diffraction grating that diffracts light; a layer thickness adjustment unit formed adjacent to the diffraction grating; and a substrate that totally internally reflects and guides light, in which the layer thickness adjustment unit includes an uneven region having a predetermined pitch or a blank region having a predetermined layer thickness, or both of the uneven region and the blank region.

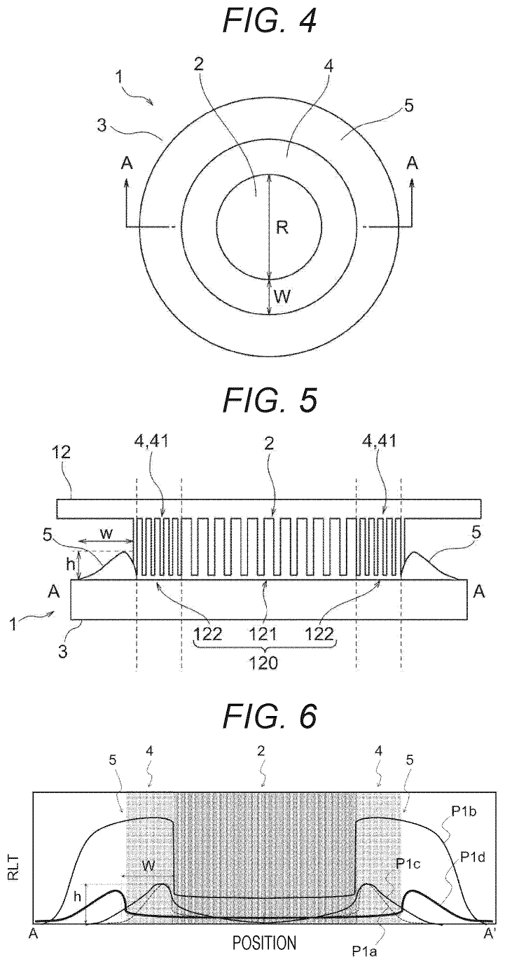

The configuration example of the light guide plate according to an embodiment of the present technology will be described with reference to FIGS. 4 and 5. FIG. 4 is a simplified top view illustrating the configuration example of the light guide plate 1 according to an embodiment of the present technology. As illustrated in FIG. 4, the light guide plate 1 according to the embodiment of the present technology includes a diffraction grating 2, a layer thickness adjustment unit 4, and the substrate 3 that totally internally reflects and guides light. The layer thickness adjustment unit 4 is formed adjacent to the diffraction grating 2. The layer thickness adjustment unit 4 does not require physical contact with the diffraction grating 2 as long as the layer thickness adjustment unit 4 is in the vicinity of the diffraction grating 2. The region 5 in which the resin material is pushed out is formed around the layer thickness adjustment unit 4.

The diffraction grating 2 diffracts light. Referring again to FIG. 1, the diffraction grating 2 may be the incident diffraction grating 21, the emission diffraction grating 22, the extended diffraction grating 23, or the return diffraction grating 24. When the diffraction grating 2 is the incident diffraction grating 21, the layer thickness adjustment unit 4 is formed around the diffraction grating 2. When the diffraction grating 2 is the emission diffraction grating 22 and the return diffraction grating 24, the layer thickness adjustment unit 4 is formed between the two diffraction gratings 2. Alternatively, when the diffraction grating 2 is the emission diffraction grating 22 and the return diffraction grating 24, the layer thickness adjustment unit 4 is formed between and around the two diffraction gratings 2.

The description returns to FIG. 4. The layer thickness adjustment unit 4 is formed around the diffraction grating 2. A diameter R of the diffraction grating 2 may be 2 mm or more or less than 2 mm. A width W of the layer thickness adjustment unit 4 is preferably 0.1 mm or more, whereby a thin and substantially uniform residual layer is formed between the diffraction grating 2 and the substrate 3.

The shapes of the diffraction grating 2 and the layer thickness adjustment unit 4 are not particularly limited. The diffraction grating 2 and the layer thickness adjustment unit 4 may be of a circle shape as in this configuration example, or may be of an oval shape, a polygon shape, or the like. A polygon includes, for example, a triangle, a quadrangle, a pentagon, a hexagon, a polygon with rounded corners, and the like. This similarly applies to other embodiments described later.

FIG. 5 is a cross-sectional view taken along line A-A illustrated in FIG. 4, and illustrates a state in which the diffraction grating 2 is formed by using the nanoimprint method. The resin pattern having an uneven shape is formed by pressing a mold 12 on which an uneven pattern is formed against a resin material and then curing the resin material. This resin pattern serves as the diffraction grating 2 and the layer thickness adjustment unit 4.

The mold 12 has a master pattern 120. The master pattern 120 has a first uneven pattern 121 and a second uneven pattern 122. The first uneven pattern 121 forms the diffraction grating 2. The second uneven pattern 122 forms an uneven region 41.

The layer thickness adjustment unit 4 includes the uneven region 41 having a predetermined pitch. A part of the resin material, which is pushed out around the diffraction grating 2 when the diffraction grating 2 is formed by using the nanoimprint method, forms the uneven region 41. The uneven region 41 has an uneven shape similar to a diffraction grating, but does not interact with the light guided by the substrate 3. That is, the uneven region 41 does not diffract the light guided by the substrate 3. The formation of the uneven region 41 reduces the amount of the resin material pushed out further than the periphery of the layer thickness adjustment unit 4. As a result, the height h of the region 5 in which the resin material swells decreases, and the width w decreases. As a result, a decrease in the MTF can be suppressed, and deterioration of the image quality can be suppressed.

Note that the uneven region 41 may have a grating vector substantially the same as the diffraction grating 2. At this time, the diffraction efficiency of the uneven region 41 is preferably very low. Specifically, the diffraction efficiency of the uneven region 41 is preferably 3% or less in all the possible orders in the uneven region 41, in a wavelength range of the light incident from the light source and guided, and in the whole angular range. This diffraction efficiency is defined as the light intensity in the light guide plate of the diffracted light of each order with respect to the intensity of the light incident on the diffraction grating from the inside of the light guide plate per single wavelength. Since the diffraction efficiency is very small, interaction with light guided by the substrate 3 may be reduced. Note that each of the diffraction grating 2 and the uneven region 41 can have one or a plurality of grating vectors.

The layer thickness adjustment unit 4 contributes to the control of the amount of the resin material. Thus, it is not necessary to reduce the amount of the resin material more than necessary in order to reduce the height h and the width w of the region 5. Therefore, the diffraction grating 2 sufficiently filled with the resin material can be formed, and a residual layer having a thin and substantially uniform thickness can be formed. As a result, the disturbance of the wavefront can be suppressed, the diffraction efficiency is improved, and the dispersion of the diffraction efficiency can be suppressed. Consequently, deterioration of the image quality can be suppressed.

As described above, the present technology can suppress deterioration of the image quality even when the amount of the resin material cannot be strictly controlled. Note that this effect is similarly provided in other embodiments described later. Therefore, in other embodiments, repeated description thereof may be omitted.

FIG. 6 is a graph obtained by plotting the thickness of the resin material in a cross section taken along line A-A illustrated in FIG. 4. The formation of the layer thickness adjustment unit 4 causes the design pattern of the resin material to have a shape indicated by P1d. In the design pattern P1d, a residual layer having a substantially uniform thickness is formed between the diffraction grating 2 and the substrate 3. The layer thickness adjustment unit 4 can control the thickness of the residual layer formed between the diffraction grating 2 and the substrate 3, the height h of the region 5 in which the resin material swells, and the width w of the region 5.

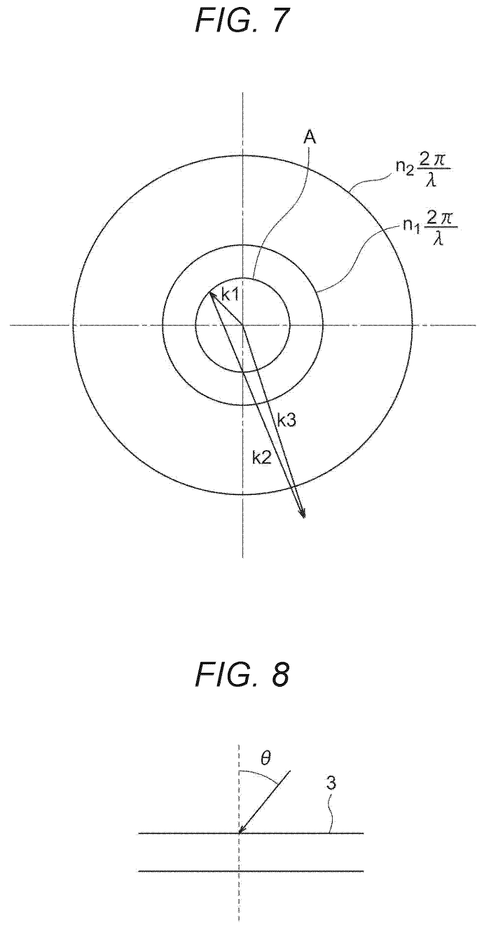

The uneven region 41 preferably has a predetermined grating vector so that the light guided by the substrate 3 is not diffracted. This point will be described with reference to FIG. 7. FIG. 7 is wave number space coordinates indicating the design example of the grating vector according to the embodiment of the present technology. In FIG. 7, vectors k1, k2, and k3 and an angle-of-view area A are illustrated.

The refractive index of air existing around the light guide plate 1 is denoted as n1. The refractive index of the layer thickness adjustment unit 4 is denoted as n2. A wavelength of light existing around the light guide plate 1 is denoted as λ. At this time, the distance from the origin to the boundary between the light guide region of the light guide plate 1 and the air existing around the light guide plate 1 is n₁2π/λ. The distance from the origin to the boundary between the light guide region of the light guide plate 1 and the evanescent region is n₂2π/λ. A range from n₁2π/λ to n₂2π/λ is the light guide region of the light guide plate 1. In this light guide region, light can be guided.

A wave number vector of light incident on the light guide plate 1 is denoted as k1. A grating vector of the uneven region 41 is denoted as k2. An end point of the grating vector k2 exists in the evanescent region. An end point of the vector k3, which is the sum of the wave number vector k1 and the grating vector k2, also exists in the evanescent region. The evanescent region exists outside the light guide region of the light guide plate 1. Therefore, the light guided by the substrate 3 and the uneven region 41 do not interact with each other. That is, the uneven region 41 does not diffract the light guided by the substrate 3.

In order for the uneven region 41 to have such a grating vector k2, the uneven region 41 preferably has a pitch smaller than that of the diffraction grating 2. Specifically, when the refractive index of air existing around the light guide plate 1 is n1, the refractive index of the layer thickness adjustment unit 4 is n2, the side-view incident angle of light incident on the layer thickness adjustment unit 4 is θ, and the wavelength of light existing around the light guide plate 1 is λ, a pitch λ of the uneven region 41 preferably satisfies the following Formula (1). Note that the pitch is a periodic interval between periodic structures (for example, binary shapes or the like).

$$[ Mathematical formula 1 ]$$

$$Λ < \frac{{n}_{2} - {n}_{1} sin θ}{λ} \qquad ( 1 )$$

The side-view incident angle θ will be described with reference to FIG. 8. FIG. 8 is a schematic diagram illustrating the side-view incident angle θ. As illustrated in FIG. 8, the side-view incident angle θ is an incident angle of light incident on the substrate 3 in a side view.

### (3) Comparison with Conventional Technology

Here, the conventional technology and the present technology will be compared and described. For example, in Patent Document 1 (U.S. Patent Application Publication No. 2005/0270312), a droplet pattern (including droplet size, position, and spacing) of a resin material is calculated by using unique software. A complex droplet pattern is formed with a very small amount. It is described that, as a result, a diffraction grating sufficiently filled with a resin material is formed, and a residual layer having a thin and substantially uniform thickness is formed.

On the other hand, the present technology does not require software requiring a calculation cost, a special injection nozzle, or the like, thus a diffraction grating sufficiently filled with a resin material can be formed and a residual layer having a thin and substantially uniform thickness can be formed.

In Patent Document 2 (U.S. Patent Application Publication No. 2020/0333527), a residual layer having a uniform thickness is formed by using spin coating. It is described that, as a result, the destruction of a diffraction grating can be prevented when a mold is separated from the diffraction grating after a diffraction grating that is inclined is formed.

However, according to the technology disclosed in Patent Document 2, there is no region formed by the resin material pushed out. Therefore, Patent Document 2 neither describes nor suggests a technology for controlling the size of this region. There is neither description nor suggestion of a technology for forming a residual layer having a thin and substantially uniform thickness.

The above contents described for the light guide plate according to the first embodiment of the present technology can be applied to other embodiments of the present technology as long as there is no technical contradiction.

### 2. Second Embodiment (Example 2 of Light Guide Plate)

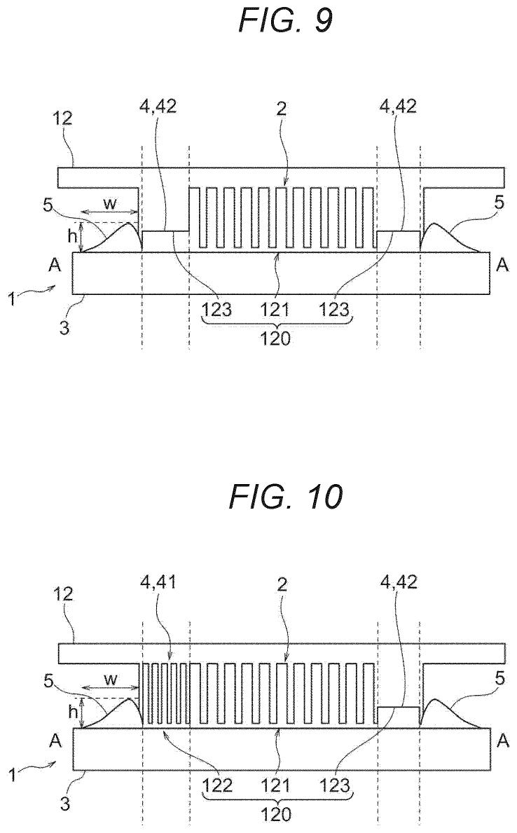

A configuration example of a light guide plate according to an embodiment of the present technology will be described with reference to FIG. 9. FIG. 9 is a cross-sectional view taken along line A-A illustrated in FIG. 4, and illustrates a state in which a diffraction grating 2 is formed by using a nanoimprint method. A resin pattern having an uneven shape is formed by pressing a mold 12 on which an uneven pattern is formed against a resin material and then curing the resin material. This resin pattern serves as the diffraction grating 2 and the layer thickness adjustment unit 4.

The mold 12 has a master pattern 120. The master pattern 120 has a first uneven pattern 121 and a second blank region 123. The first uneven pattern 121 forms a diffraction grating. The second blank region 123 forms a first blank region 42.

The layer thickness adjustment unit 4 includes the first blank region 42 having a predetermined layer thickness. A part of the resin material, which is pushed out around the diffraction grating 2 when the diffraction grating 2 is formed by using the nanoimprint method, forms the first blank region 42. The first blank region 42 does not diffract the light guided by a substrate 3. The formation of the first blank region 42 reduces the amount of the resin material pushed out further than the periphery of the layer thickness adjustment unit 4. As a result, the shape of the resin material is made to have a design pattern P1d illustrated in FIG. 6. A height h of a region 5 in which the resin material swells decreases, and a width w decreases. This makes it possible to suppress a decrease in the MTF.

The side opposite to the substrate 3 side of the first blank region 42 is preferably substantially flat. This makes it possible to suppress a decrease in the MTF.

The above contents described for the light guide plate according to the second embodiment of the present technology can be applied to other embodiments of the present technology as long as there is no technical contradiction.

### 3. Third Embodiment (Example 3 of Light Guide Plate)

A configuration example of a light guide plate according to an embodiment of the present technology will be described with reference to FIG. 10. FIG. 10 is a cross-sectional view taken along line A-A illustrated in FIG. 4, and illustrates a state in which a diffraction grating 2 is formed by using a nanoimprint method. A resin pattern having an uneven shape is formed by pressing a mold 12 on which an uneven pattern is formed against a resin material and then curing the resin material. This resin pattern serves as the diffraction grating 2 and a layer thickness adjustment unit 4.

The mold 12 has a master pattern 120. The master pattern 120 has a first uneven pattern 121, a second uneven pattern 122, and a second blank region 123. The first uneven pattern 121 forms the diffraction grating 2. The second uneven pattern 122 forms an uneven region 41. The second blank region 123 forms a first blank region 42.

The layer thickness adjustment unit 4 includes the uneven region 41 having a predetermined pitch and the first blank region 42 having a predetermined layer thickness. A part of the resin material, which is pushed out around the diffraction grating 2 when the diffraction grating 2 is formed by using the nanoimprint method, forms the uneven region 41 and the first blank region 42. The formation of the uneven region 41 and the first blank region 42 reduces the amount of the resin material pushed out further than the periphery of the layer thickness adjustment unit 4. As a result, the shape of the resin material is made to have a design pattern P1d illustrated in FIG. 6. A height h of a region 5 in which the resin material swells decreases, and a width w decreases. This makes it possible to suppress a decrease in the MTF.

The above contents described for the light guide plate according to the third embodiment of the present technology can be applied to other embodiments of the present technology as long as there is no technical contradiction.

### 4. Fourth Embodiment (Example 4 of Light Guide Plate)

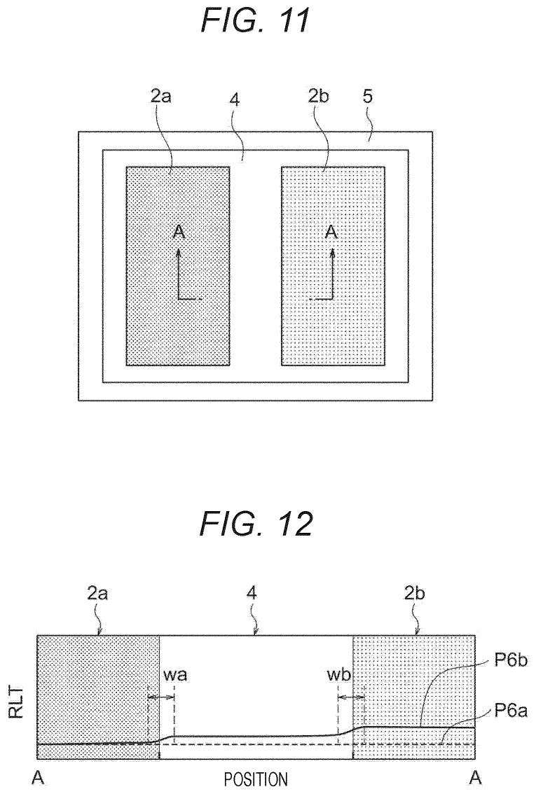

A configuration example of a light guide plate according to an embodiment of the present technology will be described with reference to FIGS. 11 and 12 FIG. 11 is a simplified top view illustrating the configuration example of a light guide plate 1 according to an embodiment of the present technology. As illustrated in FIG. 11, a first diffraction grating 2a and a second diffraction grating 2b are formed at positions close to each other. For example, the first diffraction grating 2a may be an emission diffraction grating 22 (see FIG. 1) and the second diffraction grating 2b may be a return diffraction grating 24. Alternatively, the first diffraction grating 2a may be the emission diffraction grating 22 and the second diffraction grating 2b may be an extended diffraction grating 23. Note that, in the configuration example illustrated in FIG. 4, the diffraction grating 2 may be an incident diffraction grating 21 in which no diffraction grating is formed around the diffraction grating 2.

As illustrated in FIG. 11, the layer thickness adjustment unit 4 is formed adjacent to each of the first diffraction grating 2a and the second diffraction grating 2b. A region 5 in which the resin material is pushed out is formed around the layer thickness adjustment unit 4. Although not illustrated, the layer thickness adjustment unit 4 includes an uneven region 41 having a predetermined pitch or a blank region 42 having a predetermined layer thickness, or both of the uneven region 41 and the blank region 42.

FIG. 12 is a graph obtained by plotting the thickness of the resin material in a cross section taken along line A-A illustrated in FIG. 11. Two design patterns P6a and P6b having different amounts of resin material are illustrated. In the design patterns Poa and P6b, residual layers each having a thin and substantially uniform thickness are formed between the first diffraction grating 2a and a substrate 3 (not illustrated) and between the second diffraction grating 2b and the substrate 3 (not illustrated). Note that, although not illustrated, in this configuration example, the height of the first diffraction grating 2a is higher than the height of the second diffraction grating 2b. Therefore, the residual layer formed between the second diffraction grating 2b and the substrate 3 tends to be thicker than the residual layer formed between the first diffraction grating 2a and the substrate 3.

A width wa of a transition region existing between the first diffraction grating 2a and the layer thickness adjustment unit 4 can be adjusted by the design of the layer thickness adjustment unit 4 and/or the amount of the resin material. A width wb of a transition region existing between the second diffraction grating 2b and the layer thickness adjustment unit 4 can be adjusted by the design of the layer thickness adjustment unit 4 and/or the amount of the resin material.

In addition, the layer thickness adjustment unit 4 can control, for example, the thickness of the residual layer formed between the first diffraction grating 2a and the substrate 3 (not illustrated), the thickness of the residual layer formed between the second diffraction grating 2b and the substrate 3 (not illustrated), the thickness of a residual layer formed between the layer thickness adjustment unit 4 and the substrate 3 (not illustrated), the height of the region 5 in which the resin material swells, and the width of the region 5.

The above contents described for the light guide plate according to the fourth embodiment of the present technology can be applied to other embodiments of the present technology as long as there is no technical contradiction.

### 5. Fifth Embodiment (Example 5 of Light Guide Plate)

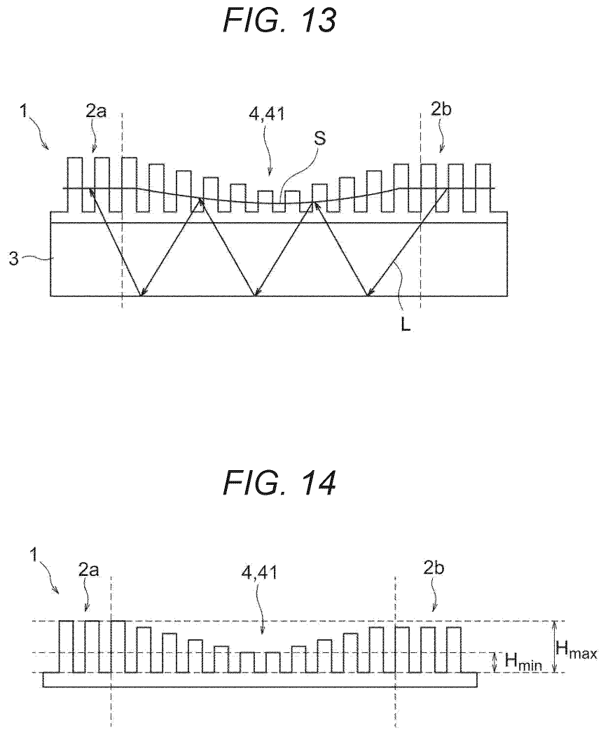

A configuration example of a light guide plate according to an embodiment of the present technology will be described with reference to FIG. 13. FIG. 13 is a simplified side view illustrating the configuration example of a light guide plate 1 according to an embodiment of the present technology. As illustrated in FIG. 13, a first diffraction grating 2a and a second diffraction grating 2b are formed at positions close to each other. A layer thickness adjustment unit 4 is formed adjacent to each of the first diffraction grating 2a and the second diffraction grating 2b. The layer thickness adjustment unit 4 includes an uneven region 41 having a predetermined pitch.

The height of the uneven region 41 of the layer thickness adjustment unit 4 is different from the heights of the diffraction gratings 2a and 2b. The height of the uneven region 41 changes according to the distances from the diffraction gratings 2a and 2b. The height of the uneven region 41 decreases as the distances from the diffraction gratings 2a and 2b increase. As a result, a residual layer having a thin and substantially uniform thickness is formed between the first diffraction grating 2a and a substrate 3. In addition, a residual layer having a thin and substantially uniform thickness is formed between the second diffraction grating 2b and the substrate 3.

When light Lis guided inside the substrate 3, the uneven region 41 whose height changes can be regarded as having a substantially flat shape S whose height is averaged. In a case where the change in height of the uneven region 41 is large, the shape S is less likely to be substantially flat, and thus the MTF may decrease.

Therefore, in order to prevent the decrease in the MTF, the change in the height of the uneven region 41 is preferably within a predetermined range. This point will be described with reference to FIG. 14. FIG. 14 is a simplified side view illustrating the configuration example of the light guide plate 1 according to the embodiment of the present technology. In the configuration example illustrated in FIG. 14, among the plurality of uneven regions 41 of the layer thickness adjustment unit 4, the highest height of the uneven region 41 is Hₘₐₓ, and the lowest height of the uneven region 41 is Hₘᵢₙ. A duty cycle of the uneven region 41 is D. The duty cycle refers to a ratio of a period during which the same width continues in a certain period in a case where the width of the diffraction grating periodically changes.

For example, it is assumed that a refractive index of the layer thickness adjustment unit 4 is 1.5, the width of the layer thickness adjustment unit 4 is 2.0 mm, and the thickness of the substrate 3 is 0.45 mm. At this time, in order to prevent a decrease in the MTF, it is preferable to satisfy the following Formula (2). When Formula (2) is satisfied, the MTF is 50% (10 cycle/deg) or more.

$$( {H}_{max} - {H}_{min} ) \times D \leq 185 nm \qquad ( 2 )$$

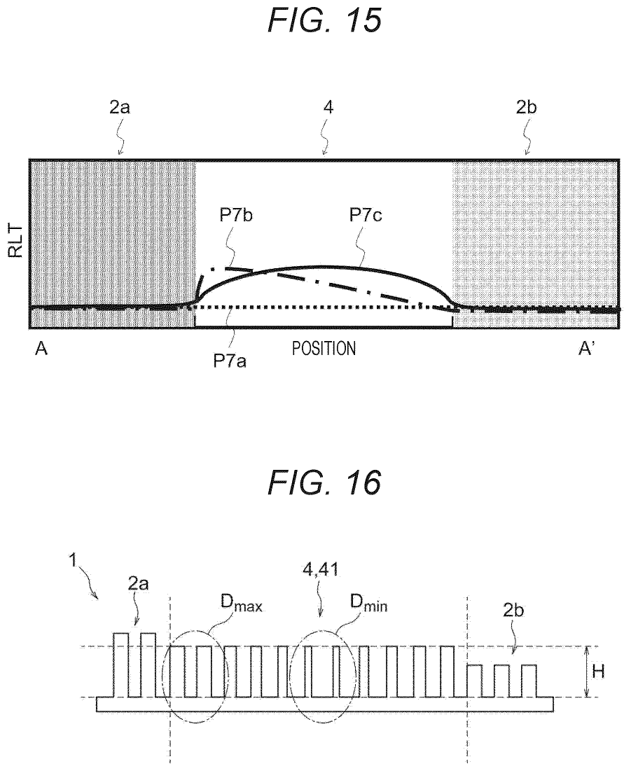

FIG. 15 is a graph obtained by plotting the thickness of the resin material formed on the light guide plate 1 illustrated in FIG. 14. Two design patterns P7a, P7b, and P7c having different amounts of resin material are illustrated. In the design patterns P7a, P7b, and P7c, residual layers each having a thin and substantially uniform thickness are formed between the first diffraction grating 2a and a substrate 3 (not illustrated) and between the second diffraction grating 2b and the substrate 3 (not illustrated).

The layer thickness adjustment unit 4 can control, for example, the thickness of the residual layer formed between the first diffraction grating 2a and the substrate 3 (not illustrated), the thickness of the residual layer formed between the second diffraction grating 2b and the substrate 3 (not illustrated), and the thickness of a residual layer formed between the layer thickness adjustment unit 4 and the substrate 3 (not illustrated).

The above contents described for the light guide plate according to the fifth embodiment of the present technology can be applied to other embodiments of the present technology as long as there is no technical contradiction.

### 6. Sixth Embodiment (Example 6 of Light Guide Plate)

A configuration example of a light guide plate according to an embodiment of the present technology will be described with reference to FIG. 16. FIG. 16 is a simplified side view illustrating the configuration example of a light guide plate 1 according to an embodiment of the present technology. As illustrated in FIG. 16, a first diffraction grating 2a and a second diffraction grating 2b are formed at positions close to each other. A layer thickness adjustment unit 4 is formed adjacent to each of the first diffraction grating 2a and the second diffraction grating 2b. The layer thickness adjustment unit 4 includes an uneven region 41 having a predetermined pitch.

A duty cycle of the uneven region 41 of the layer thickness adjustment unit 4 is different from a duty cycle of diffraction gratings 2a and 2b. The duty cycle of the uneven region 41 changes according to the distances from the diffraction gratings 2a and 2b. The duty cycle of the uneven region 41 decreases as the distances from the diffraction gratings 2a and 2b increase. As a result, a residual layer having a thin and substantially uniform thickness is formed between the first diffraction grating 2a and a substrate 3. In addition, a residual layer having a thin and substantially uniform thickness is formed between the second diffraction grating 2b and the substrate 3.

In order to prevent the decrease in the MTF, the change in the duty cycle of the uneven region 41 is preferably within a predetermined range. In this configuration example, among the plurality of uneven regions 41 of the layer thickness adjustment unit 4, the highest duty cycle of the uneven region 41 is Dₘₐₓ, and the lowest duty cycle of the uneven region 41 is Dₘᵢₙ. The height of the uneven region 41 is H.

For example, it is assumed that a refractive index of the layer thickness adjustment unit 4 is 1.5, the width of the layer thickness adjustment unit 4 is 2.0 mm, and the thickness of the substrate 3 is 0.45 mm. At this time, in order to prevent a decrease in the MTF, it is preferable to satisfy the following Formula (3). When Formula (3) is satisfied, the MTF is 50% (10 cycle/deg) or more.

$$H \times ( {D}_{max} - {D}_{min} ) \leq 185 nm \qquad ( 3 )$$

A graph obtained by plotting the thickness of the resin material formed on the light guide plate 1 can be as illustrated in FIG. 15.

The above contents described for the light guide plate according to the sixth embodiment of the present technology can be applied to other embodiments of the present technology as long as there is no technical contradiction.

### 7. Seventh Embodiment (Example 7 of Light Guide Plate)

In order to prevent a decrease in the MTF, a blank region 42 preferably has a predetermined layer thickness. For example, it is assumed that a refractive index of a layer thickness adjustment unit 4 is 1.5, the width of the layer thickness adjustment unit 4 is 2.0 mm, the thickness of a substrate 3 is 0.45 mm, a distance W from a first diffraction grating 2a to the top of the blank region is 1.0 mm, and a distance W2 from a second diffraction grating 2b to the top of the blank region is 1.0 mm. At this time, in order to prevent a decrease in the MTF, the layer thickness of the blank region 42 is preferably 185 nm or less. As a result, the MTF is 50% (10 cycle/deg) or more.

Note that, the cross-sectional shape of the blank region 42 is not particularly limited. The cross-sectional shape of the blank region 42 may be, for example, a binary shape, a trapezoidal shape, a stair shape, a dome shape, or the like. For example, when the blank region 42 has a dome shape, a graph obtained by plotting the thickness of a resin material formed on a light guide plate 1 can be as a design pattern P7c illustrated in FIG. 15. The layer thickness of the blank region 42 of the layer thickness adjustment unit 4 changes according to the distances from the first diffraction grating 20a and the second diffraction grating 20b. The layer thickness of the blank region 42 increases as the distances from the first diffraction grating 20a and the second diffraction grating 20b increase.

The above contents described for the light guide plate according to the seventh embodiment of the present technology can be applied to other embodiments of the present technology as long as there is no technical contradiction.

### 8. Eighth Embodiment (Example 8 of Light Guide Plate)

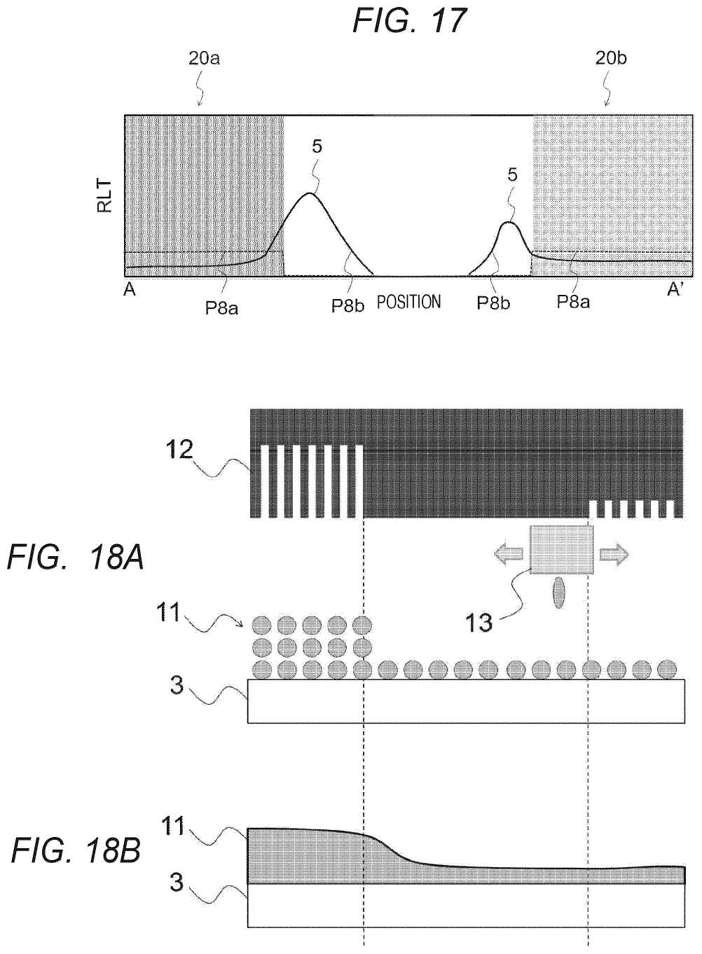

The cross-sectional view illustrated in FIG. 27 is a cross-sectional view in a case where the distance between a first diffraction grating 20a and a second diffraction grating 20b is short (for example, less than 2 mm). A case where the distance between the first diffraction grating 20a and the second diffraction grating 20b is long (for example, 2 mm or more) will be described with reference to FIG. 17. FIG. 17 is a cross-sectional view taken along line A-A illustrated in FIG. 26. In FIG. 17, design patterns P8a and P8b are illustrated. The design pattern P8a is a design pattern having an ideal resin residual layer thickness. The design pattern P8b is a design pattern when a resin material is actually dropped and formed.

In the design pattern P8b, the extra resin material for filling the first diffraction grating 20a is pushed out to the outside of the first diffraction grating 20a, and the extra resin material for filling the second diffraction grating 20b is pushed to the outside of the second diffraction grating 20b. Therefore, a region 5 is formed between the first diffraction grating 20a and the second diffraction grating 20b. This may cause disturbance of a wavefront of light to be guided. As a result, the image quality, particularly resolution, may deteriorate.

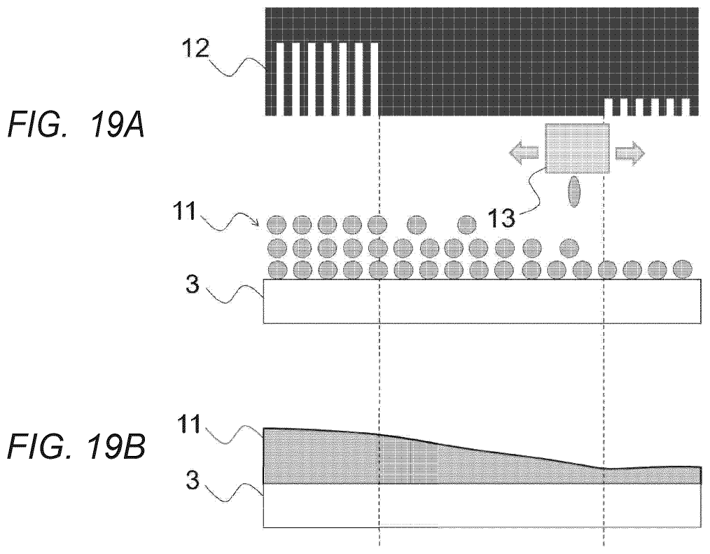

Therefore, the layer thickness of the blank region 42 of the layer thickness adjustment unit 4 may change according to the distances from the first diffraction grating 20a and the second diffraction grating 20b. This point will be described with reference to FIG. 18 and FIG. 19. FIGS. 18 and 19 are schematic views illustrating an example of a method of manufacturing a light guide plate 1 according to an embodiment of the present technology.

As illustrated in FIG. 18A, the resin material is dropped from an inkjet head 13 onto a substrate 3. When the dropped resin material is fused and the solvent evaporates, a resin material 11 is made to have a shape as illustrated in FIG. 18B. Thereafter, a mold 12 is pressed against the resin material 11 forming the first diffraction grating 20a, the first diffraction grating 20a, and the blank region 42 (all not illustrated).

In a case where the layer thickness of the blank region 42 is changed, as illustrated in FIG. 19A, the resin material is dropped from the inkjet head 13 onto the substrate 3. When the dropped resin material is fused and the solvent evaporates, the resin material 11 is made to have a shape as illustrated in FIG. 19B. The layer thickness of the blank region 42 changes according to the position. Thereafter, the mold 12 is pressed against the resin material 11 forming the first diffraction grating 20a, the first diffraction grating 20a, and the blank region 42 (all not illustrated).

In addition, in order to control light absorption, the refractive index of the layer thickness adjustment unit 4 may be different from the refractive indexes of the first diffraction grating 20a and the second diffraction grating 20b. This will be described while referring again to FIG. 11. The refractive index of the layer thickness adjustment unit 4 formed between the first diffraction grating 20a and the second diffraction grating 20b may be different from the refractive indexes of the first diffraction grating 20a and the second diffraction grating 20b. Furthermore, the refractive index of the layer thickness adjustment unit 4 formed around the first diffraction grating 20a and the second diffraction grating 20b may be different from the refractive indexes of the first diffraction grating 20a and the second diffraction grating 20b. As a result, the residual layer thickness is closer to substantially flat, and disturbance of the wavefront of the guided light can be suppressed. Consequently, deterioration of the image quality, particularly resolution, can be suppressed.

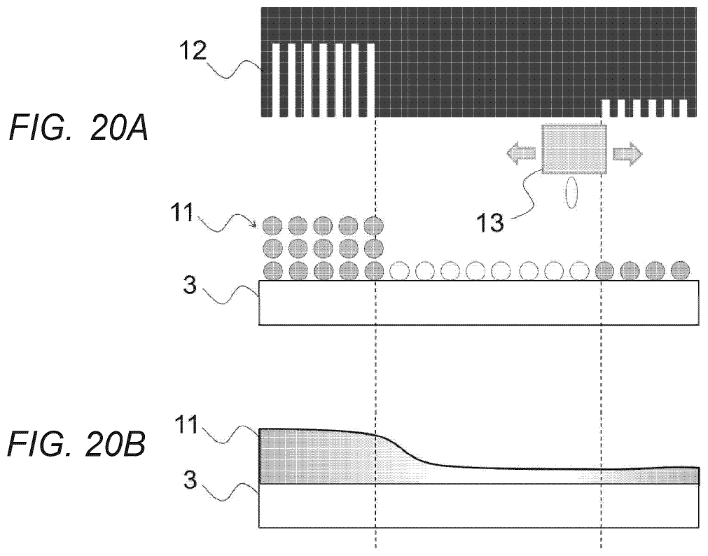

The method of manufacturing the light guide plate 1 at this time will be described with reference to FIG. 20. FIG. 20 is a schematic view illustrating an example of the method of manufacturing the light guide plate 1 according to the embodiment of the present technology.

As illustrated in FIG. 20A, the resin material is dropped from the inkjet head 13 onto the substrate 3. The refractive index of the resin material is changed according to the position. When the dropped resin material is fused and the solvent evaporates, the shape of the resin material 11 is made to have a shape illustrated in FIG. 20B. Thereafter, the mold 12 is pressed against the resin material 11 forming the first diffraction grating 20a, the first diffraction grating 20a, and the blank region 42 (all not illustrated). The refractive index of the layer thickness adjustment unit 4 is different from the refractive indexes of the first diffraction grating 20a and the second diffraction grating 20b.

The above contents described for the light guide plate according to the eighth embodiment of the present technology can be applied to other embodiments of the present technology as long as there is no technical contradiction.

### 9. Ninth Embodiment (Example of Image Display Device)

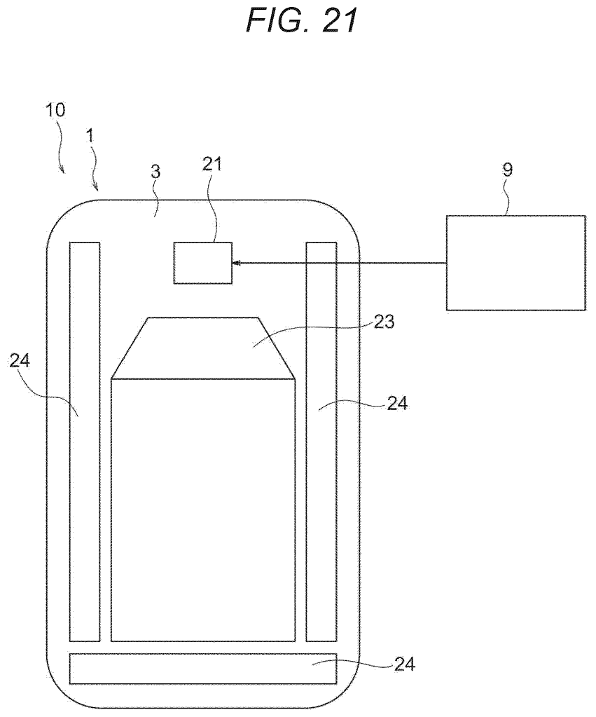

The present technology provides an image display device including the light guide plate according to the first to eighth embodiments described above and an image forming unit that emits image light to the light guide plate. This point will be described with reference to FIG. 21. FIG. 21 is a block diagram illustrating a configuration example of an image display device 10 according to an embodiment of the present technology. As illustrated in FIG. 21, the image display device 10 according to the embodiment of the present technology includes a light guide plate 1 and an image forming unit 9 that emits image light to the light guide plate 1.

The image forming unit 9 forms image light. The image forming unit 9 can use a micro panel to create a video in the image forming unit 9. For example, a self-luminous panel such as a micro LED or a micro OLED may be used as the micro panel. By using a reflective or transmissive liquid crystal, a light emitting diode (LED) light source, a laser diode (LD) light source, or the like may be used in combination with the illumination optical system.

The image light emitted from the image forming unit 9 is converted into substantially parallel light by, for example, a projection lens (not illustrated) or the like, is condensed on an incident diffraction grating 21, and is incident on the light guide plate 1. Note that the incident diffraction grating 21 may be disposed on the image forming unit 9 side or may be disposed on the side opposite to the image forming unit 9 side.

The image display device 10 may be a head mounted display (HMD) or the like worn on the head of a user. Alternatively, the image display device 10 may be disposed at a predetermined place as an infrastructure.

The above contents described for the image display device according to the ninth embodiment of the present technology can be applied to other embodiments of the present technology as long as there is no technical contradiction.

### 10. Tenth Embodiment (Example of Method of Manufacturing Light Guide Plate)

The present technology provides a method of manufacturing a light guide plate by a nanoimprint method, the method, at least, including: forming a resin material on a surface of a substrate; pressing a mold against the resin material; curing the resin material by irradiating the resin material with ultraviolet rays in a state where the mold is pressed against the resin material to transfer a master pattern of the mold to the resin material; and separating the mold from the resin material to form a resin pattern on the resin material, in which the master pattern includes a first uneven pattern that forms a diffraction grating that diffracts light, and a second uneven pattern that forms an uneven region having a predetermined pitch or a second blank region that forms a first blank region having a predetermined layer thickness, or both of the second uneven pattern and the second blank region.

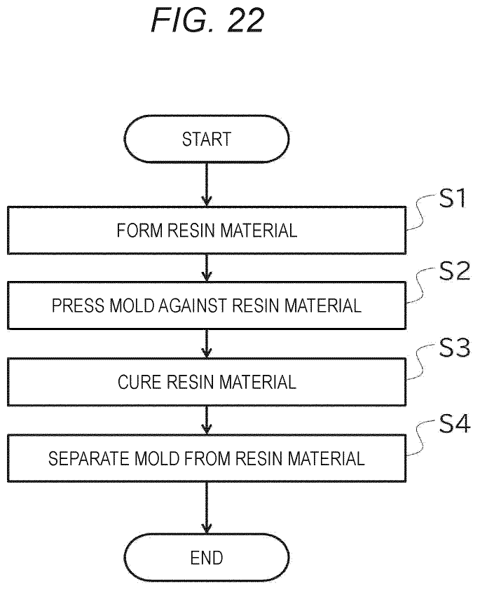

A method of manufacturing a light guide plate according to an embodiment of the present technology will be described with reference to FIG. 22. FIG. 22 is a flowchart indicating an example of a procedure of the method of manufacturing a light guide plate according to an embodiment of the present technology.

As indicated in FIG. 22, first, in step S1, a resin material is formed on a surface of a substrate. The resin material is dropped on the surface of the substrate by an inkjet method. The dropping amount of the resin material is appropriately controlled according to the volume of a diffraction grating to be formed.

Next, in step S2, a mold is pressed against the resin material.

Next, in step S3, the resin material is cured by irradiating the resin material with ultraviolet rays in a state where the mold is pressed against the resin material. As a result, a master pattern of the mold is transferred to the resin material.

The embodiment of the master pattern will be described while referring again to FIG. 5. The mold 12 has a master pattern 120. The master pattern 120 has a first uneven pattern 121 and a second uneven pattern 122. The first uneven pattern 121 forms a diffraction grating 2 that diffracts light. The second uneven pattern 122 forms an uneven region 41 having a predetermined pitch.

Another embodiment of the master pattern will be described while referring again to FIG. 9. The master pattern 120 has a first uneven pattern 121 and a second blank region 123. The first uneven pattern 121 forms a diffraction grating 2 that diffracts light. The second blank region 123 forms a first blank region 42 having a predetermined layer thickness.

Another embodiment of the master pattern will be described while referring again to FIG. 10. The master pattern 120 has a first uneven pattern 121, a second uneven pattern 122, and a second blank region 123. The first uneven pattern 121 forms a diffraction grating 2 that diffracts light. The second uneven pattern 122 forms an uneven region 41 having a predetermined pitch. The second blank region 123 forms a first blank region 42 having a predetermined layer thickness.

The description returns to FIG. 22. Next, in step S4, the mold is separated from the resin material to form a resin pattern on the resin material. According to the above procedure, the light guide plate that suppresses the deterioration of the image quality can be manufactured.

The above contents described for the method of manufacturing a light guide plate according to the tenth embodiment of the present technology can be applied to other embodiments of the present technology as long as there is no technical contradiction.

Note that embodiments of the present technology are not limited to the respective embodiments described above, but various modifications can be made to them without departing from the scope of the present technology.

Furthermore, the present technology may also adopt the following configurations.

[1]

A light guide plate including:
a diffraction grating that diffracts light;
a layer thickness adjustment unit formed adjacent to the diffraction grating; and
a substrate that totally internally reflects and guides light, in which
the layer thickness adjustment unit includes an uneven region having a predetermined pitch or a blank region having a predetermined layer thickness, or both of the uneven region and the blank region.
   [2]

The light guide plate according to [1], in which
a pitch Λ of the uneven region satisfies the following Formula (1)

$$[ Mathematical formula 1 ]$$

$$Λ < \frac{{n}_{2} - {n}_{1} sin θ}{λ} , \qquad ( 1 )$$

where
a refractive index of air existing around the light guide plate is n1,
a refractive index of the layer thickness adjustment unit is n2,
a side-view incident angle of light incident on the layer thickness adjustment unit is θ, and
a wavelength of light existing around the light guide plate is λ.
   [3]

The light guide plate according to [1], in which
a height of the uneven region is different from a height of the diffraction grating.
   [4]

The light guide plate according to [2] or [3], in which
the height of the uneven region changes according to a distance from the diffraction grating.
   [5]

The light guide plate according to [4], in which
the height of the uneven region decreases as the distance from the diffraction grating increases.
   [6]

The light guide plate according to any one of [1] to [5], in which
a duty cycle of the uneven region is different from a duty cycle of the diffraction grating.
   [7]

The light guide plate according to [6], in which
the duty cycle of the uneven region changes according to the distance from the diffraction grating.
   [8]

The light guide plate according to [7], in which
the duty cycle of the uneven region decreases as the distance from the diffraction grating increases.
   [9]

The light guide plate according to any one of [1] to [8], in which
a layer thickness of the blank region changes according to the distance from the diffraction grating.
   [10]

The light guide plate according to [9], in which
the layer thickness of the blank region increases as the distance from the diffraction grating increases.
   [11]

The light guide plate according to any one of [1] to [10], in which
a width of the layer thickness adjustment unit is 0.1 mm or more.
   [12]

The light guide plate according to any one of [1] to [11], in which
the diffraction grating is an incident diffraction grating, an emission diffraction grating, an extended diffraction grating, or a return diffraction grating.
   [13]

The light guide plate according to any one of [1] to [12], in which
the uneven region has a grating vector substantially the same as the diffraction grating, and diffraction efficiency of the uneven region is 3% or less.
   [14]

The light guide plate according to any one of [1] to [13], in which
a diameter of the diffraction grating is less than 2 mm.
   [15]

The light guide plate according to any one of [1] to [14], in which
the layer thickness adjustment unit is formed around the diffraction grating.
   [16]

The light guide plate according to any one of [1] to [15], in which
the layer thickness adjustment unit is formed between two of the diffraction gratings.
   [17]

The light guide plate according to any one of [1] to [16], in which
the layer thickness adjustment unit is formed between and around the two diffraction gratings.
   [18]

An image display device including:
the light guide plate according to any one of [1] to [17]; and
an image forming unit that emits image light to the light guide plate.
   [19]

A method of manufacturing a light guide plate by a nanoimprint method, the method, at least, including:
forming a resin material on a surface of a substrate;
pressing a mold against the resin material;
curing the resin material by irradiating the resin material with ultraviolet rays in a state where the mold is pressed against the resin material to transfer a master pattern of the mold to the resin material; and
separating the mold from the resin material to form a resin pattern on the resin material, in which
the master pattern includes
a first uneven pattern that forms a diffraction grating that diffracts light, and
a second uneven pattern that forms an uneven region having a predetermined pitch or a second blank region that forms a first blank region having a predetermined layer thickness, or both of the second uneven pattern and the second blank region.

### REFERENCE SIGNS LIST

1 Light guide plate
2 Diffraction grating
21 Incident diffraction grating
22 Emission diffraction grating
23 Extended diffraction grating
24 Return diffraction grating
3 Substrate
4 layer thickness adjustment unit
41 Uneven region
42 Blank region
5 Region
9 Image forming unit
10 Image display device
12 Mold
120 Master pattern
121 First uneven pattern
122 Second uneven pattern
123 Second blank region
S1 Forming resin material
S2 Pressing mold against resin material
S3 Curing resin material
S4 Separating mold from resin material

What is claimed is:

1. A light guide plate, comprising:
a diffraction grating that diffracts light;
a layer thickness adjustment unit formed adjacent to the diffraction grating; and
a substrate that totally internally reflects and guides light, wherein
the layer thickness adjustment unit includes an uneven region having a predetermined pitch or a blank region having a predetermined layer thickness, or both of the uneven region and the blank region.

2. The light guide plate according to claim 1, wherein
a pitch λ of the uneven region satisfies the following Formula (1),
$$[ Mathematical formula 1 ]$$
$$Λ < \frac{{n}_{2} - {n}_{1} sin θ}{λ} , \qquad ( 1 )$$
where
a refractive index of air existing around the light guide plate is n1,
a refractive index of the layer thickness adjustment unit is n2,
a side-view incident angle of light incident on the layer thickness adjustment unit is θ, and
a wavelength of light existing around the light guide plate is λ.

3. The light guide plate according to claim 1, wherein
a height of the uneven region is different from a height of the diffraction grating.

4. The light guide plate according to claim 3, wherein
the height of the uneven region changes according to a distance from the diffraction grating.

5. The light guide plate according to claim 4, wherein
the height of the uneven region decreases as the distance from the diffraction grating increases.

6. The light guide plate according to claim 1, wherein
a duty cycle of the uneven region is different from a duty cycle of the diffraction grating.

7. The light guide plate according to claim 6, wherein
the duty cycle of the uneven region changes according to a distance from the diffraction grating.

8. The light guide plate according to claim 7, wherein
the duty cycle of the uneven region decreases as the distance from the diffraction grating increases.

9. The light guide plate according to claim 1, wherein
a layer thickness of the blank region changes according to a distance from the diffraction grating.

10. The light guide plate according to claim 9, wherein
the layer thickness of the blank region increases as the distance from the diffraction grating increases.

11. The light guide plate according to claim 1, wherein
a width of the layer thickness adjustment unit is 0.1 mm or more.

12. The light guide plate according to claim 1, wherein
the diffraction grating is an incident diffraction grating, an emission diffraction grating, an extended diffraction grating, or a return diffraction grating.

13. The light guide plate according to claim 1, wherein
the uneven region has a grating vector substantially same as the diffraction grating, and diffraction efficiency of the uneven region is 3% or less.

14. The light guide plate according to claim 1, wherein
a diameter of the diffraction grating is less than 2 mm.

15. The light guide plate according to claim 1, wherein
the layer thickness adjustment unit is formed around the diffraction grating.

16. The light guide plate according to claim 1, wherein
the layer thickness adjustment unit is formed between two of the diffraction gratings.

17. The light guide plate according to claim 1, wherein
the layer thickness adjustment unit is formed between and around two of the diffraction gratings.

18. An image display device, comprising:
the light guide plate according to claim 1; and
an image forming unit that emits image light to the light guide plate.

19. A method of manufacturing a light guide plate by a nanoimprint method, the method, at least, comprising:
forming a resin material on a surface of a substrate;
pressing a mold against the resin material;
curing the resin material by irradiating the resin material with ultraviolet rays in a state where the mold is pressed against the resin material to transfer a master pattern of the mold to the resin material; and
separating the mold from the resin material to form a resin pattern on the resin material, wherein
the master pattern includes
a first uneven pattern that forms a diffraction grating that diffracts light, and
a second uneven pattern that forms an uneven region having a predetermined pitch or a second blank region that forms a first blank region having a predetermined layer thickness, or both of the second uneven pattern and the second blank region.
